(19) United States
(12) Patent Application Publication
(10) Pub. No.: US 2020/0144223 A1
(43) Pub. Date: May 7, 2020

(54) STRUCTURE OF ELECTRONIC DEVICE

(71) Applicant: Murata Manufacturing Co., Ltd., Nagaokakyo-shi (JP)

(72) Inventor: Takeaki Tamayama, Nagaokakyo-shi (JP)

(21) Appl. No.: 16/735,963

(22) Filed: Jan. 7, 2020

Related U.S. Application Data
(63) Continuation of application No. PCT/JP2018/039018, filed on Oct. 19, 2018.

(30) Foreign Application Priority Data
Oct. 26, 2017 (JP) 2017-207442

(51) Int. Cl. H01L 25/00; H05K 7/20; H05K 9/00

(52) U.S. Cl. CPC H01L 25/00; H05K 9/0081; H05K 7/20436

(57) ABSTRACT

A structure includes a first substrate having at least one of a heat-generating first electronic component and a thermally conductive first component, a second substrate having at least one of a heat-generating second electronic component and a thermally conductive second component, and a vapor chamber between the first substrate and the second substrate such that at least one of the heat-generating first electronic component and the thermally conductive first component is thermally connected to the vapor chamber, and at least one of the heat-generating second electronic component and the thermally conductive second component is thermally connected to the vapor chamber.

### CROSS REFERENCE TO RELATED APPLICATIONS

The present application is a continuation of International application No. PCT/JP2018/039018, filed Oct. 19, 2018, which claims priority to Japanese Patent Application No. 2017-207442, filed Oct. 26, 2017, the entire contents of each of which are incorporated herein by reference.

### FIELD OF THE INVENTION

The present invention relates to a structure of an electronic device.

### BACKGROUND OF THE INVENTION

In recent years, various electronic devices using heating elements, such as a semiconductor element, have been improved in performance and reduced in size, and accordingly, the heat generation density of electronic devices has increased. In general, when a predetermined temperature is exceeded, various elements, such as a semiconductor element, a battery, and the like in an electronic device not only have difficulty in maintaining their performance, but also may be damaged in some cases. Accordingly, appropriate temperature management is required, and a cooling technique that efficiently releases the heat generated in a heating element is required.

Conventionally, as shown in FIG. 11, an electronic device may have a plurality of circuit blocks separated by a shield case, and heat generated in each circuit block is radiated to a chassis sheet metal via a graphite sheet or the like (for example, FIG. 15 of Patent Document 1).

Patent Document 1: WO 2014/021046 A

### SUMMARY OF THE INVENTION

In a conventional structure 101 as shown in FIG. 11, heat generated by a heating element 103 on a substrate 102 is transferred to a chassis sheet metal 106 via a shield 104, a graphite sheet 105, and the like, and is radiated. Since a chassis sheet metal is made from aluminum in general, the thermal conductivity is relatively low. Therefore, it is difficult to diffuse heat generated from each circuit block 107 (specifically, the heating element 103) to the entire chassis sheet metal 106. That is, in a case where a plurality of circuit blocks are concentrated in the same region, heat cannot be diffused and dissipated to the entire chassis sheet metal 106. Therefore, each circuit block needs to be arranged in a plane direction, and the chassis sheet metal needs a large area. This is disadvantageous from the viewpoint of miniaturization.

Accordingly, an object of the present invention is to provide a structure excellent in heat dissipation, which diffuses heat generated in an electronic component over a wide range and has a plurality of circuit blocks.

As a result of intensive studies to solve the above-mentioned problems, the present inventors have found that heat generated from electronic components can be diffused over a wide range by using a vapor chamber instead of a chassis sheet metal, and that circuit blocks which have conventionally been arranged in a plane direction can be arranged in a stacking direction, and have arrived at the present invention.

According to a first aspect of the present invention, there is provided a structure including:

a first substrate that has at least one of a first heat-generating electronic component and a thermally conductive first component;

a second substrate that has at least one of a second heat-generating electronic component and a thermally conductive second component; and

a vapor chamber including a casing having a first sheet with a first main surface and a second main surface, a second sheet with a third main surface and a fourth main surface, the first sheet and the second sheet being joined together so as to form an internal space between the second main surface and the third main surface, a wick in the internal space, and a working medium in the internal space.

The first substrate, the vapor chamber, and the second substrate are stacked in this order to form a stacked unit, and, in the stacked unit, the first main surface of the vapor chamber faces the first substrate and the fourth main surface of the vapor chamber faces the second substrate, the at least one of the first heat-generating electronic component and the thermally conductive first component is thermally connected to the first main surface, and the at least one of the second heat-generating electronic component and the thermally conductive second component is thermally connected to the fourth main surface.

According to a second aspect of the present invention, there is provided an electronic device including the structure of the present invention.

According to a third aspect of the present invention, there is provided a server including a plurality of units each having the structure of the present invention.

According to the present invention, a first substrate having a first electronic component that is a heat-generating electronic component or a thermally conductive first component that is thermally connected to the first electronic component, and a second substrate having a second electronic component that is a heat-generating electronic component or a thermally conductive second component that is thermally connected to the second electronic component are stacked, and a vapor chamber is disposed therebetween, so that a structure having a plurality of circuit blocks that can diffuse heat generated in the electronic component over a wide range and is excellent in heat dissipation can be provided.

### BRIEF EXPLANATION OF THE DRAWINGS

FIG. 1 is a cross-sectional view of a structure 1a according to an embodiment of the present invention.

FIG. 2 is a cross-sectional view of a vapor chamber 3 used in the structure 1a shown in FIG. 1.

FIG. 3 is a cross-sectional view of a structure 1b according to another embodiment of the present invention.

FIG. 4 is a cross-sectional view of a structure 1c according to another embodiment of the present invention.

FIG. 5 is a cross-sectional view of a structure 1d according to another embodiment of the present invention.

FIG. 6 is a cross-sectional view of a structure 1e according to another embodiment of the present invention.

FIG. 7 is a cross-sectional view of a structure 1f according to another embodiment of the present invention.

FIG. 8 is a perspective view of a server 51 having the structure of the present invention.

FIG. 9 is a cross-sectional view of a unit 53 of the server 51 shown in FIG. 8.

FIG. 10 is a cross-sectional view in a case where the structure 1a shown in FIG. 1 is mounted on a portable terminal.

FIG. 11 is a cross-sectional view of a structure 101 of a conventional electronic device.

### DETAILED DESCRIPTION OF THE INVENTION

Hereinafter, a structure of an electronic device of the present invention will be described in detail. In the present description, a structure refers to, for example, a part constituting a device, particularly an electronic device, and refers to, for example, an internal structure of an electronic device and a component (for example, an electronic component) included in a device, and the like.

### First Embodiment

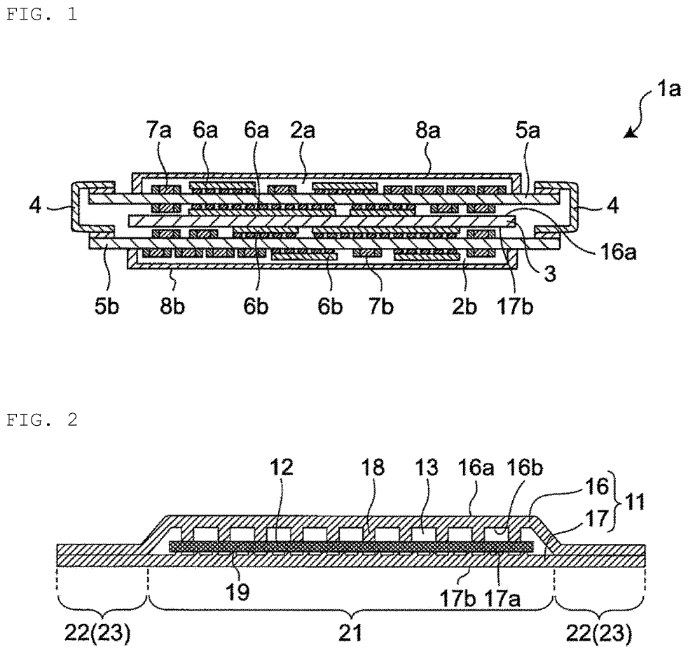

FIG. 1 shows a cross-sectional view of a structure 1a of the present embodiment.

As shown in FIG. 1, the structure 1a of the present embodiment has a configuration in which two circuit blocks 2a and 2b are placed on top of each other with a vapor chamber 3 interposed therebetween. The circuit blocks 2a and 2b are connected by a flexible substrate 4. The circuit block 2a has a heat-generating first semiconductor integrated circuit 6a and a first electronic component 7a on both main surfaces of a first substrate 5a, and also has a first shield 8a so as to cover the first semiconductor integrated circuit 6a and the first electronic component 7a on one main surface. The first semiconductor integrated circuit 6a on the other main surface is thermally connected to the vapor chamber 3, more specifically, to a first main surface 16a of the vapor chamber 3. Similarly, the circuit block 2b has a second semiconductor integrated circuit 6b and a second electronic component 7b on both main surfaces of a second substrate 5b, and also has a second shield 8b so as to enclose the second semiconductor integrated circuit 6b and the second electronic component 7b on one main surface. The second semiconductor integrated circuit 6b on the other main surface is thermally connected to the vapor chamber 3, more specifically, to a fourth main surface 17b of the vapor chamber 3. That is, the circuit block 2a and the circuit block 2b are disposed so that the other main surfaces of the circuit block 2a and the circuit block 2b face each other with the vapor chamber 3 interposed therebetween. That is, as a rough configuration, the first substrate 5a, the vapor chamber 3, and the second substrate 5b are stacked in this order to form one stacked unit, and, in the stacked unit, the vapor chamber 3 is disposed to have the first main surface 16a facing the first substrate 5a, and the fourth main surface 17b facing the second substrate 5b. Hereinafter, in the present description, one stacked unit means a unit having substrates and a vapor chamber stacked in the same order and having the same number of layers, in which the vapor chamber is disposed in the same direction. Note that the first semiconductor integrated circuit 6a, the second semiconductor integrated circuit 6b, the first electronic component 7a, and the second electronic component 7b are heat-generating electronic components.

According to the structure 1a, at least one of the heat-generating first semiconductor integrated circuit 6a and second semiconductor integrated circuit 6b (hereinafter also collectively referred to as the “semiconductor integrated circuits 6a and 6b”) is thermally connected to the vapor chamber 3 having extremely high thermal conductivity, more specifically, to at least one of the first main surface 16a and the fourth main surface 17b of the vapor chamber 3. Because of this, heat generated in the heat-generating semiconductor integrated circuits 6a and 6b thermally connected to at least one of the first main surface 16a and the fourth main surface 17b of the vapor chamber 3 is quickly diffused to the entire vapor chamber 3. That is, the structure 1a has high heat transport capability and a high heat dissipation characteristic. In the structure 1a having such high heat transport capability and a high heat dissipation characteristic, circuit blocks do not need to be disposed in a plane direction as in the conventional structure, and the circuit blocks can be disposed in a stacking direction.

In this manner, an area occupied by the circuit blocks 2a and 2b in the electronic device can be greatly reduced, which is advantageous for downsizing.

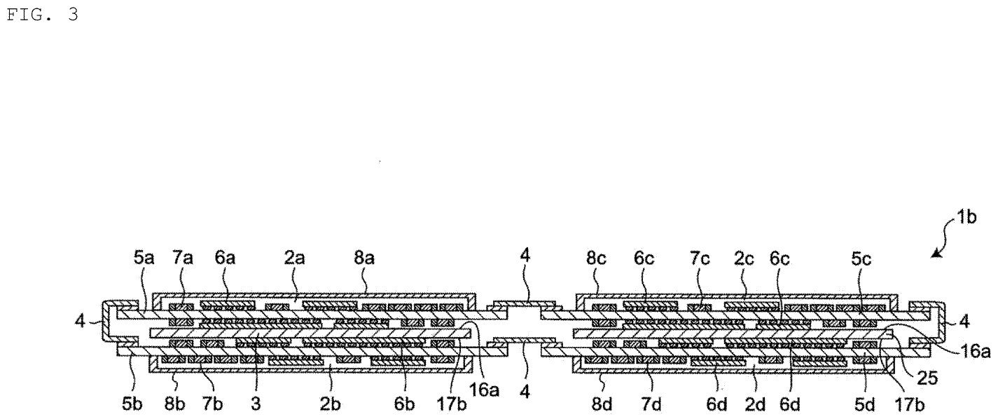

As shown in FIG. 2, the vapor chamber 3 includes a casing 11 having internal space 13, a wick 12 disposed in the internal space 13, and a working medium sealed in the internal space 13. More specifically, the casing 11 includes a first sheet 16 having the first main surface 16a and a second main surface 16b, a second sheet 17 having a third main surface 17a and the fourth main surface 17b, and the internal space 13 sandwiched between the second main surface 16b and the third main surface 17a of the first sheet 16 and the second sheet 17 joined together.

The working medium absorbs heat and evaporates in a place where the temperature of the internal space is high, moves to a place where the temperature is lower, is cooled, releases heat, and returns to a liquid phase. The working medium that has returned to the liquid phase moves to a place where the temperature is high again by a capillary force of the wick, absorbs heat, and evaporates. By repeating this, the vapor chamber operates independently without requiring external power, and can diffuse heat two-dimensionally at high speed using evaporation latent heat and condensation latent heat of the working medium. With this function, even if the heat sources are concentrated by disposing the two circuit blocks 2a and 2b in the stacking direction, heat can be diffused to other places at high speed.

Furthermore, in a case where the casing 11 of the vapor chamber 3 is made from metal, the vapor chamber 3, which exists between the circuit block 2a and the circuit block 2b, also functions as a shield between both the blocks.

In a preferred embodiment, as shown in FIG. 2, the vapor chamber 3 includes:

the casing 11 including the first sheet 16 having the first main surface 16a and the second main surface 16b and the second sheet 17 having the third main surface 17a and the fourth main surface 17b, the sheets having outer edge portions 23 joined together and facing each other;

the wick 12 disposed in the internal space 13 of the casing 11;

a first pillar 18 provided between the first sheet 16 and the wick 12;

a second pillar 19 provided between the second sheet 17 and the wick 12; and

a working medium sealed in the internal space 13 of the casing 11.

The vapor chamber 3 includes, in a plan view in a direction from the first main surface 16a to the fourth main surface 17b, a working region 21 including the internal space in which the working medium is sealed, and a quasi-working region 22 formed around the working region. Typically, the quasi-working region corresponds to the outer edge portion 23 where the first sheet and the second sheet are joined. The working region, which is a region that exerts the function as a vapor chamber, has an extremely high heat transport capability. Therefore, it is preferable to make the working region as large as possible. On the other hand, although being not a region that exerts the function as a vapor chamber, the quasi-working region is formed of a material having high thermal conductivity and has a certain degree of heat transport capability. Further, the quasi-working region, which has a sheet shape with no internal space, is excellent in durability, flexibility, and workability.

A height of the vapor chamber 3 is sufficiently smaller than a length and a width of the first main surface 16a and the fourth main surface 17b. Specifically, the length and width of the first main surface 16a and the fourth main surface 17b with respect to the height (thickness) of the vapor chamber 3 are 10 times or more, preferably 100 times or more the height (thickness). Here, the height of the vapor chamber 3 refers to a distance between the second main surface 16b and the third main surface 17a.

The thickness of the vapor chamber 3 is preferably 100 μm to 600 μm, and more preferably 200 to 500 μm.

A material constituting the first sheet 16 and the second sheet 17 is not particularly limited as long as the material has characteristics, such as thermal conductivity, strength, plasticity, flexibility, and the like, suitable for use as a vapor chamber. The material constituting the first sheet 16 and the second sheet 17 is preferably metal, such as copper, nickel, aluminum, magnesium, titanium, iron, or an alloy containing them as a main component, and, in particular, may be preferably copper. The materials constituting the first sheet 16 and the second sheet 17 may be the same or different, and are preferably the same.

In one embodiment, the first pillar 18 is provided between the first sheet 16 and the second sheet 17. In a preferred embodiment, a plurality of first pillars 18 are provided on the main surface (the second main surface 16b) of the first sheet 16 on the internal space 13 side. The first pillar 18 supports the first sheet 16 and the second sheet 17 from an inner side so that a distance between the first sheet 16 and the second sheet 17 is a predetermined distance. That is, the first pillar 18 functions as a column that supports the first sheet 16 and the second sheet 17 of the vapor chamber 3. By installing the first pillar 18 inside the casing 11, the casing can be prevented from being deformed in cases where the inside of the casing is depressurized, external pressure is applied from the outside of the casing, and the like.

In one embodiment, the second pillar 19 is provided between the first sheet 16 and the second sheet 17. In a preferred embodiment, a plurality of second pillars 19 are provided on the main surface (the third main surface 17a) of the second sheet 17 on the internal space 13 side. By having the plurality of second pillars 19, the working medium can be held between the second pillars, and an amount of the working medium in the vapor chamber of the present invention can be easily increased. By increasing the amount of the working medium, the heat transport capability of the vapor chamber 3 is improved. Here, the second pillar refers to a portion having a height that is relatively higher than the surroundings. The second pillar includes a portion protruding from the main surface such as a columnar portion, and also includes a portion that is relatively high due to recessed portion formed on the main surface such as a groove.

The height of the first pillar 18 is greater than the height of the second pillar 19.

In one embodiment, the height of the first pillar 18 is preferably 1.5 times to 100 times, more preferably 2 times to 50 times, further preferably 3 times to 20 times, and further more preferably 3 times to 10 times the height of the second pillar 19.

The shape of the first pillar 18, which is not particularly limited as long as the first sheet 16 and the second sheet 17 can be supported, is preferably a columnar shape, and may be, for example, a cylindrical shape, a prismatic shape, a truncated cone shape, a truncated pyramid shape, or the like.

The material forming the first pillar 18 is not particularly limited, and is, for example, metal, such as copper, nickel, aluminum, magnesium, titanium, iron, or an alloy containing them as a main component, and, in particular, may be preferably copper.

In a preferred embodiment, the material forming the first pillar 18 is the same material as one or both of the first sheet 16 and the second sheet 17.

The height of the first pillar 18 can be appropriately set according to the thickness of the desired vapor chamber, and is preferably 50 μm to 500 μm, more preferably 100 μm to 400 μm, further preferably 100 μm to 200 μm, for example, 125 μm to 150 μm. Here, the height of the first pillar means the height of the vapor chamber in the thickness direction.

The thickness of the first pillar 18 is not particularly limited as long as the first pillar 18 provides the strength capable of suppressing deformation of the casing of the vapor chamber, and, for example, an equivalent circle diameter of a cross section perpendicular to the height direction of the first pillar 18 may be 100 μm to 2000 μm, preferably 300 μm to 1000 μm. By increasing the equivalent circle diameter of the first pillar, deformation of the casing of the vapor chamber can be further suppressed. Further, by reducing the equivalent circle diameter of the first pillar, wider space can be secured for vapor of the working medium to move.

The arrangement of the first pillars 18 is not particularly limited, but is preferably arranged evenly, for example, in a lattice point form so that the first pillars 18 are disposed at a uniform interval.

By evenly arranging the first pillars, a uniform strength can be secured over the entire vapor chamber.

The number and interval of the first pillars 18 are not particularly limited, and the number of first pillars 18 may be preferably 0.125 to 0.5, more preferably 0.2 to 0.3 per 1 mm² of the main surface area of one sheet that defines the internal space of the vapor chamber. By increasing the number of first pillars, deformation of the vapor chamber (or casing) can be further suppressed. Further, by reducing the number of first pillars, wider space can be secured for vapor of the working medium to move.

The first pillar 18 may be formed integrally with the first sheet 16, or may be manufactured separately from the first sheet 16, and then fixed to a predetermined location.

The height of the second pillar 19 is not particularly limited, and may be preferably 1 μm to 100 μm, more preferably 5 μm to 50 μm, and further preferably 15 μm to 30 μm. By increasing the height of the second pillar, a holding amount of the working medium can be increased. Further, by further lowering the height of the second pillar, wider space (space on the first pillar side) can be secured for vapor of the working medium to move. Therefore, the heat transport capability of the vapor chamber can be adjusted by adjusting the height of the second pillar.

The distance between the second pillars 19 is not particularly limited, and may be preferably 1 μm to 500 μm, more preferably 5 μm to 300 μm, and further preferably 15 μm to 150 μm. By reducing the distance between the second pillars, the capillary force can be further increased. Further, the transmittance can be further increased by increasing the distance between the second pillars.

The shape of the second pillar 19 is not particularly limited, and may be a cylindrical shape, a prismatic shape, a truncated cone shape, a truncated pyramid shape, or the like. Further, the shape of the second pillar 19 may be a wall shape, that is, a shape by which a groove is formed between adjacent second pillars 19.

The second pillar 19 may be formed integrally with the second sheet 17, or may be manufactured separately from the second sheet 17, and then fixed at a predetermined location.

The wick 12 is not particularly limited as long as the wick 12 has a structure capable of moving the working medium by a capillary force. A capillary structure that exerts a capillary force for moving the working medium is not particularly limited, and may be a publicly-known structure used in a conventional vapor chamber. For example, examples of the capillary structure include a fine structure having irregularities formed by a pore, a groove, a protrusion, or the like, such as a fiber structure, a groove structure, a mesh structure, and the like.

The thickness of the wick 12 is not particularly limited, and may be, for example, 5 μm to 200 μm, preferably 10 μm to 80 μm, more preferably 30 μm to 50 μm.

The size and the shape of the wick 12 are not particularly limited; however, the wick 12 preferably has a size and a shape so that the wick 12 can be continuously installed from an evaporation section to a condensation section inside the casing.

The working medium is not particularly limited as long as the working medium can cause a gas-liquid phase change in the environment inside the casing, and, for example, water, alcohols, a CFC substitute, and the like can be used. In one embodiment, the working medium is an aqueous compound, preferably water.

Note that, in FIG. 2, the wick 12, which is an independent member, may be formed integrally with the casing. For example, instead of providing the wick 12 in the vapor chamber shown in FIG. 2, the second pillar 19 formed on the wall surface of the casing can be used as the wick.

Further, the vapor chamber used in the present invention is not particularly limited, as long as the vapor chamber has a planar casing having internal space, a wick disposed in the internal space, and a working medium sealed in the internal space. For example, although the pillar supports the casing in FIG. 2, the wick may be partially provided without providing the pillar, and the casing may be supported by the wick.

The circuit block 2a has the first semiconductor integrated circuit 6a and the first electronic component 7a on the first substrate 5a, and also has, on one main surface, the first shield 8a so as to cover the first semiconductor integrated circuit 6a and the first electronic component 7a on the one main surface. Similarly, the circuit block 2b has the second semiconductor integrated circuit 6b and the second electronic component 7b on the second substrate 5b, and also has, on one main surface, the second shield 8b so as to cover the second semiconductor integrated circuit 6b and the second electronic component 7b on the one main surface. The circuit blocks 2a and 2b are connected by the flexible substrate 4.

The first substrate 5a and the second substrate 5b (hereinafter also collectively referred to as “substrates 5a and 5b”) are not particularly limited as long as they are circuit boards that are generally used, and a printed circuit board is preferably used.

The first semiconductor integrated circuit 6a and the second semiconductor integrated circuit 6b are not particularly limited as long as they are heat-generating electronic components. For example, the first semiconductor integrated circuit 6a and the second semiconductor integrated circuit 6b may be a semiconductor element that is an electronic component generating a large amount of heat.

The semiconductor integrated circuit is not particularly limited, and examples of the semiconductor integrated circuit include heat-generating semiconductor integrated circuits, such as an accelerated processing unit (APU), a central processing unit (CPU), a power management integrated circuit (PMIC), and a memory.

At least one of the heat-generating semiconductor integrated circuit 6a and the electronic component 7a and at least one of the heat-generating semiconductor integrated circuit 6b and the electronic component 7b are thermally connected to the vapor chamber 3, more specifically, to the first main surface 16a and the fourth main surface 17b of the vapor chamber 3. Such thermal connection may be performed by bringing both into direct contact, or may be performed via another thermally conductive member, for example, a metal member, such as thermal grease or solder, interposed therebetween.

Here, the “thermal grease” is a viscous substance having high thermal conductivity, and for example, a substance, in which particles of metal or metal oxide having high thermal conductivity are dispersed in modified silicone or the like, is used.

The first electronic component 7a and the second electronic component 7b (hereinafter also collectively referred to as “electronic components 7a and 7b”) are various electronic components, such as a capacitor and an inductor. Note that, instead of or in addition to the electronic components 7a and 7b, components, such as wiring and a terminal, that constitute part of the circuit block and conduct heat may be provided.

Note that the structure of the present invention is not limited to the configuration shown in FIG. 1, and preferably has a configuration, in which the substrate 5a has at least one of the first semiconductor integrated circuit 6a, the first electronic component 7a, or a component, such as wiring and a terminal, thermally connected to the vapor chamber 3, more specifically, to the first main surface 16a of the vapor chamber 3, and the substrate 5b has at least one of the second semiconductor integrated circuit 6b, the second electronic component 7b, or a component, such as wiring or a terminal, thermally connected to the vapor chamber 3, more specifically, to the fourth main surface 17b of the vapor chamber 3. In one embodiment, the structure of the present invention includes at least one of the first semiconductor integrated circuit 6a, the first electronic component 7a, the second semiconductor integrated circuit 6b, and the second electronic component 7b, which are thermally connected to the vapor chamber 3, more specifically, to the first main surface 16a or the fourth main surface 17b of the vapor chamber 3. While the number of semiconductor integrated circuits 6a and 6b is such that four for the semiconductor integrated circuit 6a and four for the semiconductor integrated circuit 6b in the embodiment shown in FIG. 1, the present invention is not limited to the above. For example, the number of semiconductor integrated circuits 6a and 6b may be one, two, or three or more. In a preferred embodiment, there is at least one semiconductor integrated circuit 6a, and at least one semiconductor integrated circuit 6b.

In the embodiment shown in FIG. 1, the first semiconductor integrated circuit 6a and the second semiconductor integrated circuit 6b exist on both main surfaces of the first substrate 5a and the second substrate 5b, respectively; however, installation locations of the semiconductor integrated circuits 6a and 6b are not particularly limited. For example, the semiconductor integrated circuits 6a and 6b may exist only on the main surfaces of the substrates 5a and 5b on the vapor chamber 3 side, or may exist on both main surfaces of the substrates 5a and 5b.

Further, the number of electronic components 7a and 7b is not particularly limited.

In the embodiment shown in FIG. 1, the electronic components 7a and 7b are separated from the vapor chamber 3; however, the present invention is not limited to the above. In one embodiment, the electronic components 7a and 7b may be thermally connected to the vapor chamber 3. Further, components, such as wiring and a terminal, having thermal conductivity may be thermally connected to the vapor chamber 3. When these components are thermally connected to the vapor chamber 3, a heat dissipation characteristic of the structure is improved. More specifically, a component, such as wiring and a terminal, having thermal conductivity thermally connected to one or more of the heat-generating semiconductor integrated circuits 6a and 6b and the heat-generating electronic components 7a and 7b may be thermally connected to the vapor chamber 3, more specifically, to the first main surface 16a or the fourth main surface 17b of the vapor chamber 3.

The configuration may be such that, in one embodiment, the first semiconductor integrated circuit 6a on the substrate 5a is thermally connected to the vapor chamber 3, more specifically, to the first main surface 16a of the vapor chamber 3, and only the second electronic component 7b out of the second semiconductor integrated circuit 6b and the second electronic component 7b on the substrate 5b is thermally connected to the vapor chamber 3, more specifically, to the fourth main surface 17b of the vapor chamber 3.

The first shield 8a is provided on one main surface of the first substrate 5a, that is, on a surface opposite to the surface on the vapor chamber 3 side of the first substrate 5a, so as to cover the first semiconductor integrated circuit 6a and the first electronic component 7a. The second shield 8b is provided on one main surface of the second substrate 5b, that is, on a surface opposite to the surface on the vapor chamber 3 side of the second substrate 5b, so as to cover the second semiconductor integrated circuit 6b and the second electronic component 7b. Note that the first shield 8a or the second shield 8b do not need to be provided directly on the surface of the first substrate 5a or the second substrate 5b, and may be provided so as to cover the surface of the first substrate 5a or the second substrate 5b. A shield may be provided on a main surface side opposite to the main surface facing the vapor chamber 3 of at least one of the first substrate 5a and the second substrate 5b.

The first shield 8a and the second shield 8b (hereinafter also collectively referred to as “shields 8a and 8b”) are not particularly limited, and may be a shield that is generally used. The shields 8a and 8b are made from, for example, a good conductor, such as metal, or a magnetic material, preferably highly conductive metal, and more preferably highly conductive and thermally conductive metal. In particular, by forming the shield from metal having high thermal conductivity, an effect of further improving a heat dissipation characteristic can be obtained in addition to an electromagnetic wave shielding effect.

Note that the shields 8a and 8b are not essential configurations and do not need to exist. In a case the shield exits, the configuration may be such that only one of the shields 8a and 8b exists. Further, not all the semiconductor integrated circuits and electronic components existing on one main surface need to be covered, and the configuration may be such that only part of them is covered.

The flexible substrate 4 is formed by connection wiring provided on a thin flexible resin sheet of polyimide or the like. In addition to the connection wiring, an electronic component, such as a capacitor, may be mounted on the flexible substrate 4. The substrates 5a and 5b and the flexible substrate 4 are connected via a connector component or a conductive bonding material, such as solder, interposed therebetween.

Note that the electrical connection between the circuit blocks is not essential and the configuration is not particularly limited to the above.

### Second Embodiment

FIG. 3 shows a cross-sectional view of a structure 1b of the present embodiment.

As shown in FIG. 3, the structure 1b schematically has a structure in which two structures 1a described above are connected in the horizontal direction (the plane direction of the substrates 5a and 5b). That is, the structure 1b includes two stacked units, and the two stacked units are provided in different regions in a plan view in a direction from the first main surface 16a to the fourth main surface 17b. Specifically, the structure 1b includes the circuit blocks 2a and 2b stacked with the vapor chamber 3 interposed therebetween, and circuit blocks 2c and 2d stacked with a vapor chamber 25 interposed therebetween. The circuit blocks 2a and 2c are adjacent to each other in the horizontal direction, and the circuit blocks 2b and 2d are adjacent to each other in the horizontal direction.

The circuit block 2a and the circuit block 2c adjacent in the horizontal direction are connected by the flexible substrate 4 at the ends of the adjacent substrates 5a and 5c. Similarly, the circuit blocks 2b and 2d adjacent in the horizontal direction are connected by another flexible substrate 4 at the ends of the adjacent substrates 5b and 5d. Furthermore, the stacked circuit blocks 2a and 2b are connected by another flexible substrate 4 at an end opposite to the portion where the substrates 5c and 5d are connected. Similarly, the stacked circuit blocks 2c and 2d are connected by another flexible substrate 4 at an end opposite to the portion where the substrates 5a and 5b are connected. Note that the electrical connection between the circuit blocks is not essential and the configuration is not particularly limited to the above.

The circuit blocks 2a and 2b are the same as the circuit blocks 2a and 2b in the structure 1a.

The circuit block 2c has a third semiconductor integrated circuit 6c and a third electronic component 7c on the third substrate 5c, and also has, on one main surface, a third shield 8c so as to cover the third semiconductor integrated circuit 6c and the third electronic component 7c on the one main surface.

The circuit block 2d has a fourth semiconductor integrated circuit 6d and a fourth electronic component 7d on the fourth substrate 5d, and also has, on one main surface, a fourth shield 8d so as to cover the fourth semiconductor integrated circuit 6d and the fourth electronic component 7d on the one main surface.

The third substrate 5c and the fourth substrate 5d have characteristics similar to those of the first substrate 5a and the second substrate 5b. The third semiconductor integrated circuit 6c and the fourth semiconductor integrated circuit 6d have characteristics similar to those of the first semiconductor integrated circuit 6a and the second semiconductor integrated circuit 6b. The third electronic component 7c and the fourth electronic component 7d have characteristics similar to those of the first electronic component 7a and the second electronic component 7b.

The third shield 8c and the fourth shield 8d have characteristics similar to those of the first shield 8a and the second shield 8b.

The vapor chamber 25 has characteristics similar to those of the vapor chamber 3.

At least one of the first semiconductor integrated circuit 6a in the circuit block 2a and the second semiconductor integrated circuit 6b in the circuit block 2b is thermally connected to the vapor chamber 3 as in the structure 1a, more specifically, to at least one of the first main surface 16a and the fourth main surface 17b of the vapor chamber 3, and heat generated from the first semiconductor integrated circuit 6a and the second semiconductor integrated circuit 6b is quickly diffused by the vapor chamber 3 and released. At least one of the third semiconductor integrated circuit 6c in the circuit block 2c and the fourth semiconductor integrated circuit 6d in the circuit block 2d is thermally connected to the vapor chamber 25, more specifically, to at least one of the first main surface 16a and the fourth main surface 17b of the vapor chamber 25, and heat generated from the third semiconductor integrated circuit 6c and the fourth semiconductor integrated circuit 6d is quickly diffused by the vapor chamber 25 and released.

Further, the vapor chamber 3 existing between the circuit block 2a and the circuit block 2b can also function as a shield, and shields an electromagnetic wave between the circuit block 2a and the circuit block 2b. Similarly, the vapor chamber 25 existing between the circuit block 2c and the circuit block 2d can also function as a shield, and shields an electromagnetic wave between the circuit block 2c and the circuit block 2d.

With the configuration as described above, in spite of having an installation area similar to that of the conventional structure 101, the structure 1b allows twice as many circuit blocks to be disposed.

Note that, in the present embodiment, the two structures 1a are connected in the horizontal direction; however, the present invention is not limited to this configuration, and one or more structures 1a can be connected in the horizontal direction. That is, two or more stacked units may exist.

### Third Embodiment

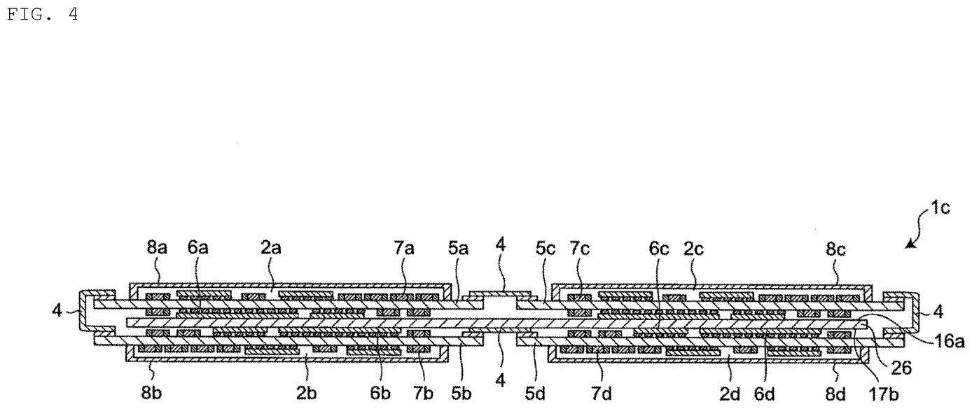

FIG. 4 shows a cross-sectional view of a structure 1c of the present embodiment.

As shown in FIG. 4, the structure 1c has a structure in which the vapor chamber 3 and the vapor chamber 25 of the structure 1b described above are replaced with one vapor chamber 26. That is, the structure 1c has two stacked units in different regions in a plan view in a direction from the first main surface to the fourth main surface, which share one vapor chamber 26. On one main surface of the vapor chamber 26, the circuit block 2a and the circuit block 2c are disposed. On the other main surface of the vapor chamber 26, the circuit block 2b is disposed at a position facing the circuit block 2a across the vapor chamber 26, and the circuit block 2d is disposed at a position facing the circuit block 2c across the vapor chamber 26. The circuit block 2a and the circuit block 2c adjacent in the horizontal direction are connected by the flexible substrate 4 at the ends of the adjacent substrates 5a and 5c. Similarly, the circuit blocks 2b and 2d adjacent in the horizontal direction are connected by another flexible substrate 4 at the ends of the adjacent substrates 5b and 5d. Furthermore, the stacked circuit blocks 2a and 2b are connected by another flexible substrate 4 at an end opposite to the portion where the substrates 5c and 5d are connected. Similarly, the stacked circuit blocks 2c and 2d are connected by another flexible substrate 4 at an end opposite to the portion where the substrates 5a and 5b are connected. Note that the electrical connection between the circuit blocks is not essential and the configuration is not particularly limited to the above.

The substrates 5a and 5b, the semiconductor integrated circuits 6a and 6b, the electronic components 7a and 7b, and the shields 8a and 8b in the circuit blocks 2a and 2b are similar to the substrates 5a and 5b, the semiconductor integrated circuits 6a and 6b, the electronic components 7a and 7b, and the shields 8a and 8b in the structure 1a.

The circuit block 2c has the third semiconductor integrated circuit 6c and the third electronic component 7c on the third substrate 5c, and also has, on one main surface, the shield 8c so as to cover the third semiconductor integrated circuit 6c and the third electronic component 7c on the one main surface.

The circuit block 2d has the fourth semiconductor integrated circuit 6d and the fourth electronic component 7d on the fourth substrate 5d, and also has, on one main surface, the shield 8d so as to cover the fourth semiconductor integrated circuit 6d and the fourth electronic component 7d on the one main surface.

The third substrate 5c and the fourth substrate 5d have characteristics similar to those of the first substrate 5a and the second substrate 5b. The third semiconductor integrated circuit 6c and the fourth semiconductor integrated circuit 6d have characteristics similar to those of the first semiconductor integrated circuit 6a and the second semiconductor integrated circuit 6b. The third electronic component 7c and the fourth electronic component 7d have characteristics similar to those of the first electronic component 7a and the second electronic component 7b.

The shield 8c and the shield 8d have characteristics similar to those of the shield 8a and the shield 8b.

The vapor chamber 26 extends to the outside of the regions of the first substrate 5a and the second substrate 5b in a plan view in the direction from the first main surface 16a to the fourth main surface 17b, and extends to the regions of the third substrate 5c and the fourth substrate 5d. The vapor chamber 26 has characteristics similar to those of the vapor chamber 3 except that the area of the main surface is large.

At least one of the first semiconductor integrated circuit 6a in the circuit block 2a and the second semiconductor integrated circuit 6b in the circuit block 2b is thermally connected to the vapor chamber 26 like the structure 1a, more specifically, to at least one of the first main surface 16a and the fourth main surface 17b of the vapor chamber 26, and heat generated from the first semiconductor integrated circuit 6a and the second semiconductor integrated circuit 6b is quickly diffused by the vapor chamber 26 and released.

At least one of the third semiconductor integrated circuit 6c in the circuit block 2c and the fourth semiconductor integrated circuit 6d in the circuit block 2d is thermally connected to the vapor chamber 26, more specifically, to at least one of the first main surface 16a and the fourth main surface 17b of the vapor chamber 26, and heat generated from the third semiconductor integrated circuit 6c and the fourth semiconductor integrated circuit 6d is quickly diffused by the vapor chamber 26 and released.

Further, the vapor chamber 26 existing between the circuit block 2a and the circuit block 2b and between the circuit block 2c and the circuit block 2d can also function as a shield, and shields an electromagnetic wave between the circuit block 2a and the circuit block 2b and between the circuit block 2c and the circuit block 2d.

With the configuration as described above, in spite of having an installation area similar to that of the conventional structure 101, the structure 1b allows twice as many circuit blocks to be disposed. Furthermore, since one large vapor chamber is used, a thermal diffusion region becomes large and heat dissipation characteristics are improved.

Note that, in the present embodiment, the two structures 1a are connected in the horizontal direction; however, the present invention is not limited to this configuration, and one or more structures 1a can be connected in the horizontal direction. That is, two or more stacked units may exist.

### Fourth Embodiment

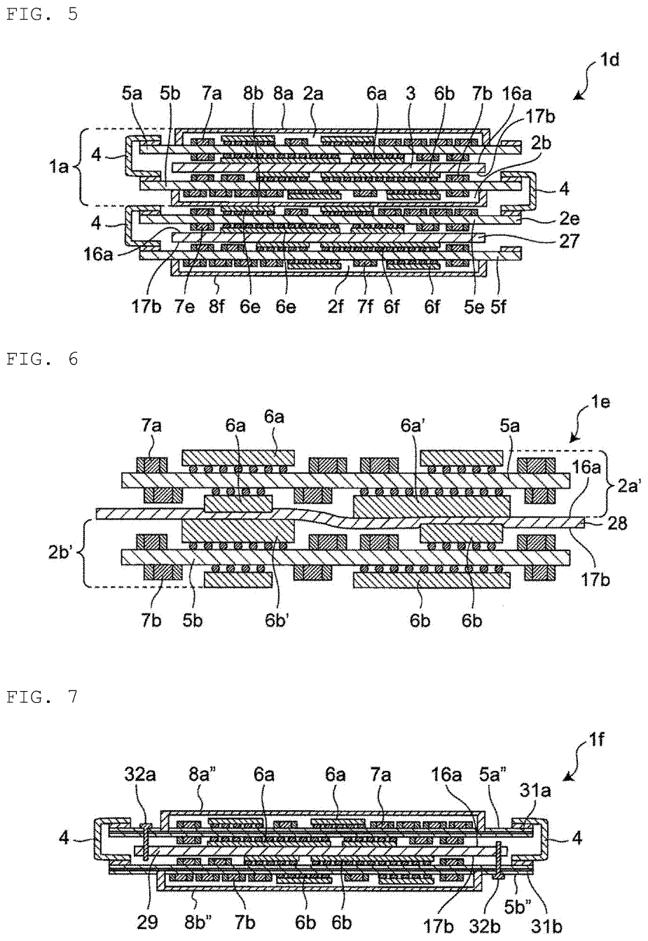

FIG. 5 shows a cross-sectional view of a structure 1d of the present embodiment.

As shown in FIG. 5, the structure 1d schematically has a structure in which two structures 1a described above are connected in the stacking direction (the vertical direction in the diagram). That is, the structure 1d includes two stacked units, and the two stacked units are provided in the region in a plan view in a direction from the first main surface 16a to the fourth main surface 17b. Specifically, in the structure 1d, a circuit block 2e is stacked below the circuit blocks 2a and 2b that are stacked with the vapor chamber 3 interposed therebetween similarly to the structure 1a, and a circuit block 2f is further stacked below the circuit block 2e. The circuit block 2a and the circuit block 2b stacked with the vapor chamber 3 interposed therebetween are connected by the flexible substrate 4 at one end (a left end in the diagram) of the substrates 5a and 5b. The circuit block 2b and the circuit block 2e that are stacked are connected by another flexible substrate 4 at ends (ends on the right side of the diagram) of the substrates 5b and 5e, which are located on the opposite side of the portion where the substrates 5a and 5b are connected. The circuit block 2e and the circuit block 2f that are stacked with a vapor chamber 27 interposed therebetween are connected by another flexible substrate 4 at ends (ends on the left side of the diagram) of the substrates 5e and 5f, which are located on the opposite side of the portion where the substrates 5b and 5e are connected. That is, the flexible substrates 4 that connect the substrates are provided alternately on the left and right. Note that the electrical connection between the circuit blocks is not essential and the configuration is not particularly limited to the above.

The circuit blocks 2a and 2b are the same as the circuit blocks 2a and 2b in the structure 1a.

The circuit block 2e has a third semiconductor integrated circuit 6e and a third electronic component 7e on the third substrate 5e.

The circuit block 2f has a fourth semiconductor integrated circuit 6f and a fourth electronic component 7f on the fourth substrate 5f, and also has, on one main surface (main surface facing downward in the diagram), a third shield 8f so as to cover the fourth semiconductor integrated circuit 6f and the fourth electronic component 7f on the one main surface.

The third substrate 5e and the fourth substrate 5f have characteristics similar to those of the first substrate 5a and the second substrate 5b. The third semiconductor integrated circuit 6e and the fourth semiconductor integrated circuit 6f have characteristics similar to those of the first semiconductor integrated circuit 6a and the second semiconductor integrated circuit 6b. The third electronic component 7e and the fourth electronic component 7f have characteristics similar to those of the first electronic component 7a and the second electronic component 7b.

The third shield 8f has characteristics similar to those of the shields 8a and 8b.

The vapor chamber 27 has characteristics similar to those of the vapor chamber 3.

At least one of the first semiconductor integrated circuit 6a in the circuit block 2a and the second semiconductor integrated circuit 6b in the circuit block 2b is thermally connected to the vapor chamber 3, more specifically, to at least one of the first main surface 16a and the fourth main surface 17b of the vapor chamber 3, and heat generated from the first semiconductor integrated circuit 6a and the second semiconductor integrated circuit 6b is quickly diffused by the vapor chamber 3 and released. At least one of the third semiconductor integrated circuit 6e in the circuit block 2e and the fourth semiconductor integrated circuit 6f in the circuit block 2f is thermally connected to the vapor chamber 27, more specifically, to at least one of the first main surface 16a and the fourth main surface 17b of the vapor chamber 27, and heat generated from the third semiconductor integrated circuit 6e and the fourth semiconductor integrated circuit 6f is quickly diffused by the vapor chamber 27 and released. Further, at least one of the third semiconductor integrated circuit 6e and the third electronic component 7e in the circuit block 2e is thermally connected to the second shield 8b of the circuit block 2b.

Further, the vapor chamber 3 existing between the circuit block 2a and the circuit block 2b can also function as a shield, and shields an electromagnetic wave between the circuit block 2a and the circuit block 2b. Similarly, the vapor chamber 27 existing between the circuit block 2e and the circuit block 2f can also function as a shield, and shields an electromagnetic wave between the circuit block 2e and the circuit block 2f. Further, the second shield 8b of the circuit block 2b shields an electromagnetic wave between the circuit block 2b and the circuit block 2e.

With the configuration as described above, in the structure 1d, the number of circuit blocks to be disposed can be increased while the installation area is suppressed.

Note that, in the present embodiment, four circuit blocks are provided in the stacking direction; however, one or more circuit blocks can be added as in the case of addition of the circuit block 2e and the circuit block 2f. That is, two or more stacked units may exist.

### Fifth Embodiment

FIG. 6 shows a cross-sectional view of a structure 1e of the present embodiment.

As shown in FIG. 6, the structure 1e schematically has a structure in which the vapor chamber in the structure 1a is curved. Specifically, the structure 1e has a structure in which a circuit block 2a′ and a circuit block 2b′ are placed on top of each other with a vapor chamber 28 interposed therebetween. The circuit block 2a′ has the heat-generating first semiconductor integrated circuit 6a and the first electronic component 7a on one main surface of the first substrate 5a, and has the heat-generating first semiconductor integrated circuit 6a, a first semiconductor integrated circuit 6a′, and the first electronic component 7a on the other main surface. The first semiconductor integrated circuit 6a and the first semiconductor integrated circuit 6a′ on the other main surface are thermally connected to the vapor chamber 28, more specifically, to the first main surface 16a of the vapor chamber 28. Similarly, the circuit block 2b has the second semiconductor integrated circuit 6b and the second electronic component 7b on one main surface of the second substrate 5b, and has the second semiconductor integrated circuit 6b, a second semiconductor integrated circuit 6b′, and the second electronic component 7b on the other main surface. The second semiconductor integrated circuit 6b and the second semiconductor integrated circuit 6b′ on the other main surface are thermally connected to the vapor chamber 28, more specifically, to the fourth main surface 17b of the vapor chamber 28.

The circuit blocks 2a′ and 2b′ are disposed so that the other main surfaces of the substrates 5a and 5b face the vapor chamber 28, and the semiconductor integrated circuits 6a′ and 6b′ are thicker than the semiconductor integrated circuits 6a and 6b. Further, the first semiconductor integrated circuit 6a and the second semiconductor integrated circuit 6b′ are disposed to face each other, and the first semiconductor integrated circuit 6a′ and the second semiconductor integrated circuit 6b are disposed to face each other. As a result, the vapor chamber 28 is closer to the first substrate 5a than to the second substrate 5b in a location where the first semiconductor integrated circuit 6a and the second semiconductor integrated circuit 6b′ face each other, is closer to the second substrate 5b than to the first substrate 5a in a location where the first semiconductor integrated circuit 6a′ and the second semiconductor integrated circuit 6b face each other, and is curved between the two locations. Since the vapor chamber may have flexibility, the above configuration is possible. Since the structure of the present invention can be configured as described above, even in a case where semiconductor integrated circuits and electronic components having different thicknesses are used, they can be suitably stacked. That is, in the present embodiment, the vapor chamber 28 has flexibility, and has two regions at different heights in the stacking direction.

The vapor chamber 28 is pressed by the first semiconductor integrated circuit 6a and the second semiconductor integrated circuit 6b, and has a surface recessed. Since the vapor chamber has internal space and cushioning properties, the above configuration is made possible. Since the structure of the present invention can be configured as described above, even in a case where there is a slight difference in thickness between the semiconductor integrated circuit and the electronic component, each component can be appropriately brought into contact with the vapor chamber. Further, the cushioning properties of the vapor chamber can protect each semiconductor integrated circuit and electronic component from impact.

The vapor chamber 28 extends to the outside of the regions of the first substrate 5a and the second substrate 5b. Extending to the outside of the regions of the substrates 5a and 5b in this way is advantageous for heat dissipation from the vapor chamber 28.

The circuit blocks 2a′ and 2b′ have the first semiconductor integrated circuit 6a′ and the second semiconductor integrated circuit 6b′, respectively, and are similar to the circuit blocks 2a and 2b in the structure 1a except that the circuit blocks 2a′ and 2b′ have no shield.

The vapor chamber 28 has characteristics similar to those of the vapor chamber 3 except that the vapor chamber 28 is curved.

The first semiconductor integrated circuits 6a and 6a′ in the circuit block 2a′ and the second semiconductor integrated circuits 6b and 6b′ in the circuit block 2b are thermally connected to the vapor chamber 28 like the structure 1a, more specifically, to the first main surface 16a and the fourth main surface 17b of the vapor chamber 28, and heat generated from the first semiconductor integrated circuits 6a and 6a′ and the second semiconductor integrated circuits 6b and 6b′ is quickly diffused by the vapor chamber 28 and released.

Further, the vapor chamber 28 existing between the circuit block 2a′ and the circuit block 2b′ can also function as a shield, and shields an electromagnetic wave between the circuit block 2a′ and the circuit block 2b′.

### Sixth Embodiment

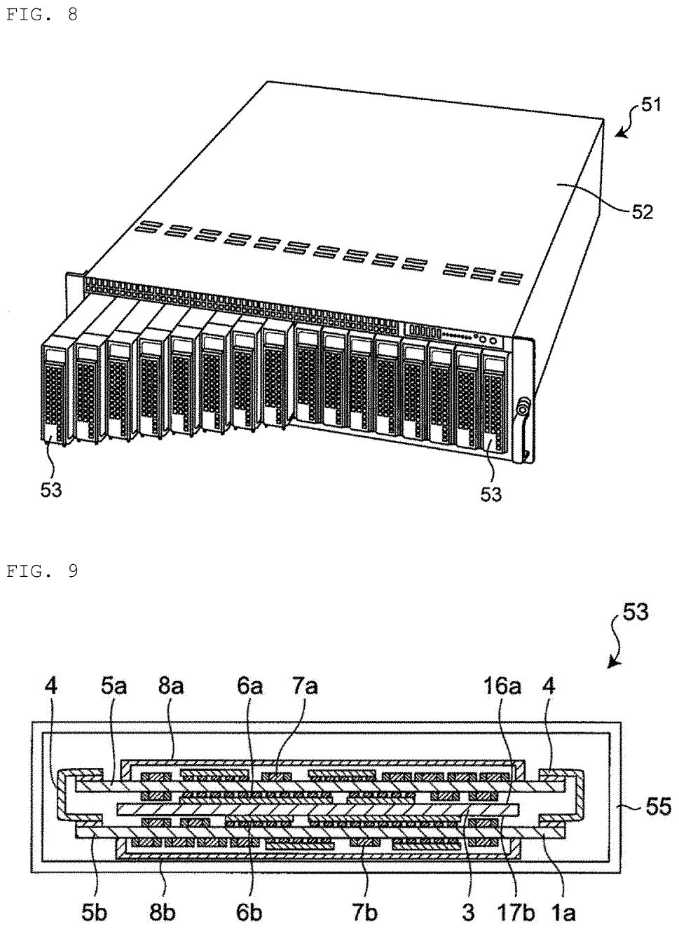

FIG. 7 shows a cross-sectional view of a structure 1f of the present embodiment.

As shown in FIG. 7, the structure 1f schematically has a structure in which a ground electrode is embedded in the substrate of the structure 1a described above, a shield is thermally connected to the ground electrode inside the substrate, and the substrate is further fixed to the vapor chamber by a fixing member.

The structure 1f has a structure in which two circuit blocks 2a″ and 2b″ are placed on top of each other with a vapor chamber 29 interposed therebetween. The circuit blocks 2a″ and 2b″ are connected by the flexible substrate 4. Note that the electrical connection between the circuit blocks is not essential and the configuration is not particularly limited to the above.

The circuit block 2a″ has the heat-generating first semiconductor integrated circuit 6a and the first electronic component 7a on both main surfaces of a first substrate 5a″, and also has a first shield 8a″ so as to cover the first semiconductor integrated circuit 6a and the first electronic component 7a on one main surface. A first ground electrode 31a is embedded in the first substrate 5a″. An end of the first shield 8a″ extends to the inside of the first substrate 5a″ and is thermally connected to the first ground electrode 31a embedded in the first substrate 5a″. The first semiconductor integrated circuit 6a on the other main surface is thermally connected to the vapor chamber 29, more specifically, to the first main surface 16a of the vapor chamber 29. The first substrate 5a″ is fixed to the vapor chamber 29 by a fixing member 32a so that the other main surface faces the main surface of the vapor chamber 29. The fixing member 32a penetrates the first substrate 5a″ and further penetrates the vapor chamber 29. The fixing member 32a is thermally connected to the first ground electrode 31a embedded in the first substrate 5a″ and the vapor chamber 29. That is, the vapor chamber 29 and the first ground electrode 31a are thermally connected. Further, the vapor chamber 29 may also be electrically connected to the first ground electrode 31a, that is, grounded.

The circuit block 2b″ has the heat-generating second semiconductor integrated circuit 6b and the second electronic component 7b on both main surfaces of a second substrate 5b″, and also has a second shield 8b″ so as to cover the second semiconductor integrated circuit 6b and the second electronic component 7b on one main surface. A second ground electrode 31b is embedded in the second substrate 5b″. An end of the second shield 8b″ extends to the inside of the second substrate 5b″ and is thermally connected to the second ground electrode 31b embedded in the second substrate 5b″. The second semiconductor integrated circuit 6b on the other main surface is thermally connected to the vapor chamber 29, more specifically, to the fourth main surface 17b of the vapor chamber 29. The second substrate 5b″ is fixed to the vapor chamber 29 by a fixing member 32b so that the other main surface faces the main surface of the vapor chamber 29. The fixing member 32b penetrates the second substrate 5b″ and further penetrates the vapor chamber 29. The fixing member 32b is thermally connected to the second ground electrode 31b embedded in the second substrate 5b″ and the vapor chamber 29. That is, the vapor chamber 29 and the second ground electrode 31b are thermally connected. Further, the vapor chamber 29 may also be electrically connected to the second ground electrode 31b, that is, grounded.

The first substrate 5a″ and the second substrate 5b″ have characteristics similar to those of the first substrate 5a and the second substrate 5b in the structure 1a, except that the ground electrodes 31a and 31b are included in the inside.

The ground electrodes 31a and 31b may be metal plates or foil embedded in the substrates 5a″ and 5b″. The metal constituting the ground electrodes 31a and 31b is not particularly limited, and examples of the metal include copper, silver, aluminum, gold, and the like.

The fixing members 32a and 32b are not particularly limited as long as the fixing members 32a and 32b can fix the substrate to the vapor chamber, and examples of the fixing members 32a and 32b include screws, bolts, pins, connectors, and the like.

The material for forming the fixing members 32a and 32b is not particularly limited, and is preferably one having high thermal conductivity, and examples of the material include metal materials, specifically, iron, aluminum, copper, an alloy of these, and the like.

The vapor chamber 29 has characteristics similar to those of the vapor chamber 3 except that the vapor chamber 29 has a through hole (for example, a screw hole) through which the fixing members 32a and 32b penetrate. The through hole is preferably provided in a quasi-working region of the vapor chamber. The quasi-working region, which does not have internal space and is excellent in durability, flexibility, and workability, is appropriate for providing the through hole.

The first semiconductor integrated circuit 6a in the circuit block 2a″ and the second semiconductor integrated circuit 6b in the circuit block 2b″ are thermally connected to the vapor chamber 29, more specifically, to the first main surface 16a and the fourth main surface 17b of the vapor chamber 29, and heat generated from the first semiconductor integrated circuit 6a and the second semiconductor integrated circuit 6b is quickly diffused by the vapor chamber 29 and released. Furthermore, the heat diffused by the vapor chamber 29 is diffused to the first ground electrodes 31a and 31b via the fixing members 32a and 32b. Therefore, the structure 1f of the present embodiment is more excellent in heat dissipation. Furthermore, the heat diffused to the ground electrodes 31a and 31b is diffused to the shields 8a′ and 8b′. Therefore, the structure 1f of the present embodiment is more excellent in heat dissipation. Further, since the ground electrodes 31a and 31b may also function as a shield, the structure 1f of the present embodiment having the ground electrodes 31a and 31b is advantageous also from the viewpoint of electromagnetic wave shielding.

Note that, in the embodiment shown in FIG. 7, both the substrate 5a″ and the substrate 5b″ have the ground electrode; however, the configuration may be such that only one of them has the ground electrode. Further, although both the substrate 5a″ and the substrate 5b″ are fixed to the vapor chamber 29 by the fixing member and thermally connected to the vapor chamber 29, the configuration may be such that only one of them is fixed and thermally connected.

Further, in the embodiment shown in FIG. 7, both the first shield 8a″ and the second shield 8b″ are thermally connected to the ground electrode; however, the configuration may be such that only one of them is thermally connected to the ground electrode.

The structure of the present invention is described above with reference to several embodiments; however, the present invention is not limited to the above structure, and the design can be changed without departing from the gist of the present invention.

As described above, the structure of the present invention makes it possible to incorporate a plurality of circuit blocks in relatively small space in, for example, an electronic device, and further has excellent heat dissipation, so that the structure is suitable for electronic devices for various applications.

Therefore, the present invention also provides an electronic device having the structure of the present invention.

Examples of the electronic device include, but not limited to, a portable terminal, such as a mobile phone or a smartphone, a personal computer (PC), a tablet terminal, a server (particularly a unit constituting a server), and the like.

In a preferred embodiment, the electronic device may be a server. The structure of the present invention is used in particular for each blade in a blade type server.

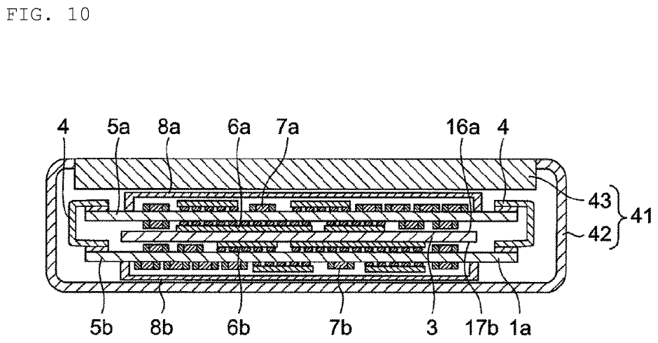

FIG. 8 shows a server 51 having a plurality of units each having the structure of the present invention. The server 51 of the present invention has a plurality of units 53 in a casing 52.

Each of the units 53 includes the structure of the present invention. For example, as shown in FIG. 9, the structure 1a of the present invention shown in FIG. 1 is incorporated in a casing 55 of the unit 53.

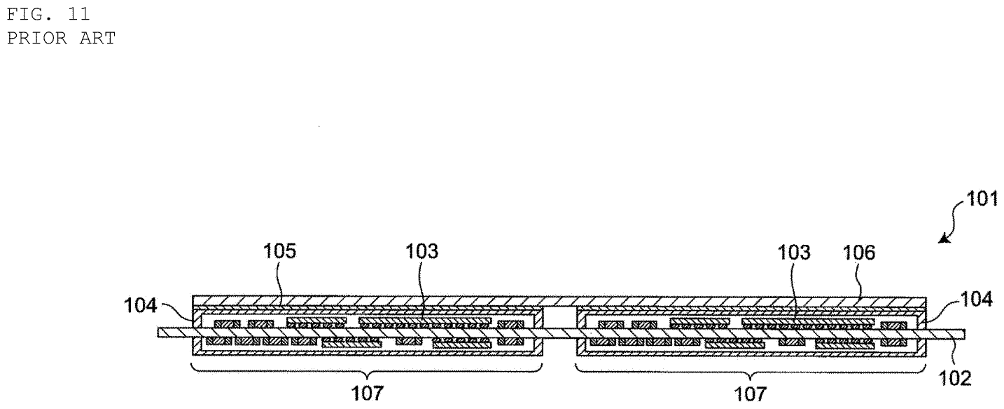

In another preferred embodiment, the electronic device may be a portable terminal. For example, as shown in FIG. 10, the structure 1a is incorporated in space defined by a casing 42 and a display 43 of a portable terminal 41.

In one embodiment, the structure of the present invention is thermally connected to a casing of an electronic device. Heat dissipation is further improved by thermally connecting the structure of the present invention to the casing of the electronic device.

The structure of the present invention, which occupies a small area and has high heat dissipation, can be suitably used in various electronic devices.

### DESCRIPTION OF REFERENCE SYMBOLS

1a, 1b, 1c, 1d, 1e, 1f: Structure

2a, 2b, 2c, 2d, 2e, 2f, 2a′, 2b′, 2a″, 2b″: Circuit block

3: Vapor chamber

4: Flexible substrate

5a: First substrate

5b: Second substrate

5c: Third substrate

5d: Fourth substrate

5e: Third substrate

5f: Fourth substrate

5a″: First substrate

5b″: Second substrate

6a: First semiconductor integrated circuit

6b: Second semiconductor integrated circuit

6c: Third semiconductor integrated circuit

6d: Fourth semiconductor integrated circuit

6e: Third semiconductor integrated circuit

6f: Fourth semiconductor integrated circuit

7a: First electronic component

7b: Second electronic component

7c: Third electronic component

7d: Fourth electronic component

7e: Third electronic component

7f: Fourth electronic component

8a: First shield

8b: Second shield

8c: Third shield

8d: Fourth shield

8f: Third shield

8a″: First shield

8b″: Second shield

11: Casing

12: Wick

13: Internal space

16: First sheet

16a: First main surface

16b: Second main surface

17: Second sheet

17a: Third main surface

17b: Fourth main surface

18: First pillar

19: Second pillar

21: Working region

22: Quasi-working region

23: Outer edge portion

25: Vapor chamber

26: Vapor chamber

27: Vapor chamber

28: Vapor chamber

29: Vapor chamber

31a: First ground electrode

31b: Second ground electrode

41: Portable terminal

42: Casing

43: Display

51: Server

52: Casing

53: Unit

55: Casing

101: Conventional structure

102: Substrate

103: Heating element

104: Shield

105: Graphite sheet

106: Chassis sheet metal

107: Circuit block

1. A structure comprising:
a first substrate that has at least one of a first heat-generating electronic component and a thermally conductive first component;
a second substrate that has at least one of a second heat-generating electronic component and a thermally conductive second component; and
a vapor chamber including a casing having a first sheet with a first main surface and a second main surface, a second sheet with a third main surface and a fourth main surface, the first sheet and the second sheet being joined together so as to form an internal space between the second main surface and the third main surface, a wick in the internal space, and a working medium in the internal space, wherein
the first substrate, the vapor chamber, and the second substrate are stacked in this order to form a stacked unit,
in the stacked unit, the first main surface of the vapor chamber faces the first substrate and the fourth main surface of the vapor chamber faces the second substrate,
the at least one of the first heat-generating electronic component and the thermally conductive first component is thermally connected to the first main surface, and
at least one of the second heat-generating electronic component and the thermally conductive second component is thermally connected to the fourth main surface.

2. The structure according to claim 1, wherein at least one of the first substrate and the second substrate has a ground electrode, and the casing of the vapor chamber is thermally connected to the ground electrode.

3. The structure according to claim 1, further comprising a shield covering a first main surface of at least one of the first substrate and the second substrate opposite to a second main surface of the at least one of the first substrate and the second substrate facing the vapor chamber.

4. The structure according to claim 3, wherein the shield is thermally connected to a ground electrode of the at least one of the first substrate and the second substrate.

5. The structure according to claim 4, further comprising a fixing member fixing the at least one of the first substrate and the second substrate to the vapor chamber.

6. The structure according to claim 3, wherein the shield is a first shield covering the first main surface of the first substrate, and the structure further comprises a second shield covering a first main surface of the second substrate opposite to a second main surface of the second substrate facing the vapor chamber.

7. The structure according to claim 6, wherein the first shield is thermally connected to a first ground electrode of the first substrate and the second shield is thermally connected to a second ground electrode of the second substrate.

8. The structure according to claim 7, further comprising a first fixing member fixing the first substrate to the vapor chamber, and a second fixing member fixing the second substrate to the vapor chamber.

9. The structure according to claim 1, wherein the vapor chamber extends outside of a region defined by a perimeter of the first substrate and the second substrate as viewed in a plan view in a direction from the first main surface to the fourth main surface.

10. The structure according to claim 1, wherein the vapor chamber is formed of a flexible material and has a first region and a second region at different heights in a stacking direction of the stacked unit.

11. The structure according to claim 1, wherein the stacked unit is a first stacked unit, and the structure further comprises at least a second stacked unit, and the first and second stacked units are arranged to overlap each other within a same region as viewed in a plan view of the structure.

12. The structure according to claim 1, wherein the stacked unit is a first stacked unit, and the structure further comprises at least a second stacked unit, and the first and second stacked units are arranged in different regions as viewed in a plan view of the structure.

13. The structure according to claim 12, wherein the first and second stacked units share a single vapor chamber that extends between the first and second stacked units.

14. The structure according to claim 1, further comprising a flexible substrate that connected the first substrate to the second substrate.

15. An electronic device comprising the structure according to claim 1.

16. A server comprising a plurality of units, each of the plurality of units having the structure according to claim 1.
